(19) United States
(12) Patent Application Publication
(10) Pub. No.: US 2010/0314454 A1
(43) Pub. Date: Dec. 16, 2010

(54) CONFIGURABLE EXTERNAL RFID TAG

(75) Inventor: Tai Won Youn, Albuquerque, NM (US)

Correspondence Address: CAESAR, RIVISE, BERNSTEIN,;COHEN & POKOTILOW, LTD., 11TH FLOOR, SEVEN PENN CENTER, 1635 MARKET STREET, PHILADELPHIA, PA, 19103-2212, US

(73) Assignee: TC LICENSE LTD., Hummelstown, PA (US)

(21) Appl. No.: 12/775,889

(22) Filed: May 7, 2010

Related U.S. Application Data
(60) Provisional application No. 61/187,252, filed on Jun. 15, 2009.

(51) Int. Cl. G06K 19/077; H05K 13/00; B23P 11/00

(52) U.S. Cl. 235/492; 29/592.1; 29/428

(57) ABSTRACT

RFID tags are disclosed having uniform electronics assemblies, but which fit into a variety of housings. This manufacturing technique allows for high volume production of tag electronics while keeping the mounting means adaptable to a variety of support structures. This ability to host a variety of support structures is important at least in the field of RFID tags for motorcycles, because motorcycles have varying configurations and no one tag would fit all motorcycles.

### CROSS-REFERENCE TO RELATED APPLICATIONS

This utility application claims the benefit under 35 U.S.C. §119(e) of Provisional Application Ser. No. 61/187,252 filed on Jun. 15, 2009 and entitled Configurable External RFID Tag, the entire disclosure of which is incorporated by reference herein.

### FIELD OF THE INVENTION

This invention relates generally to RFID transponder systems and more particularly to RFID transponders for use in electronic toll collection systems that are mounted externally on a vehicle.

### BACKGROUND OF THE INVENTION

RFID (radio frequency identification) tags have been used for highway toll collection, railroad cars and multi-modal shipping container tracking, inventory control, access control, fleet maintenance, hospital access, parking lots access, and manufacturing lines for decades. Externally mounted RFID tags have been offered by various RFID manufactures including AWID, Intermec, and TransCore, including license plate tags for toll collections and rail tags for railroad applications with high power radar signals. Generally, tags and tag mounting hardware are designed for a specific application and mounting arrangement. New applications require new tag configurations. Rarely are tags interchangeable onto equipment or vehicles having differing mounting surfaces. Thus, a manufacturer must produce and stock a wide variety of tags for the various applications and mounting surfaces. The result is high inventory costs because each application requires the stocking of a different tag type.

An example of an application where variety of mounting surfaces must be accommodated is externally mounted vehicle tags. Conventional electronic toll tags are mounted internally, usually on a windshield. Mounting of the tag inside the cab environment of the vehicle can be done with low cost adhesive strips and hook and lock (Velcro®) style fasteners. The fastening is not critical in that environment since the tag will still be in the vehicle even if it separates from the fastening surface. This is not the case for external mounting. There, the tag must be weather-tight and securely fastened to survive shock, vibration, moisture, humidity and temperature extremes in addition to thwarting vandalism and theft of the tag. Unlike the cab environment, where the tag can be conveniently fasted to a dashboard or windshield with minimal difficulty, a external tag must be more securely fastened. Usually this will be to a metal vehicle part, such as a bumper, fender or license plate. The available external mounting surfaces on different vehicles each present different attachment problems. The metal of a fender, bumper or license plate presents an additional challenge in that it can severely alter the impedance of the tag's antenna. One application where internal mounting is not an option is a motorcycle. A mounted tag on a motorcycle is always an externally mounted tag and must survive the aforementioned elements. With the possible exception of the license plate, there is no common surface configuration that is universal to all motorcycles for which a single “one size fits all” tag mount would work.

An externally-mounted tag is necessary for motorcycles and also for cars with metalized windshields. Motorcycles and metalized windshield cars present different engineering challenges. Vehicles having metalized windshields come with varying locations and the space availability to install a tag, for example, because some vehicles have two windshield wipers, while others come with one. With respect to motorcycles, there are a few hundred different motorcycle styles with a wide variation for the usable space where a tag can be installed. Many motorcycles have non-metallic components such as cowlings, fenders and windshields that would be likely tag mounting locations.

Tag performance depends on the operating frequency, physical size, the electrical properties of the surrounding material and the gap between the antenna element and metallic ground planes. For instance, a dipole antenna (FIG. 1) works well for applications with a metal reflector such as motorcycle and metalized windshields, while an aperture antenna (FIG. 2) works well for applications without a metal reflector such as road signs and bullet-proof windshields.

Therefore it would be desirable that an externally mounted tag have following features; Mechanically configurable by inter-locking the ROD assembly with the bracket; Electrically configurable so that different antenna with the same mounting hole positions would be over-molded with the same outside plastics for different applications which might require a different shape of antenna; As small and thin as possible; Cost effective to cover a wide range of applications; Narrow and long dipole shape so that the tags can be used on the most motorcycles with various and limited mounting space; Designed for mounting directly on metal or other materials; Mechanically strong enough to be operational under the severe environmental conditions of vibration, temperature, ultraviolet light and aging; Usable for vehicles, containers and other assets; Hermetically sealed assembly housing the antenna assembly in protective plastic; and Adhesive backing for simple installation or fastened by screws.

An alternative approach to specialized tags for each different mounting arrangement is to produce a universal tag insert housing the tag electronics in a single type casing and a number of mounting packages into which the tag fits. Because the main cost is in the tag electronics, this concept reduces the stocking burden on manufacturers and distributors of having many types of tags. Instead, the more expensive component, the electronics, is a universal component that can be applied to a host of applications. The only component that must be stocked in a variety of configurations then becomes the mounting package into which the tag fits.

Thus, a need exists for an RFID tag that combines a universal electronics assembly that is housed in a variety of enclosures, each enclosure being adapted for mounting to a different structure, such as vehicles with differing mounting surface configurations, different kinds of vehicles or differing applications altogether.

### SUMMARY OF THE INVENTION

In an embodiment of the invention there is disclosed an RFID tag having an electronics assembly (an RFID Tag insert) and a tag housing (bracket) having mounting points for mounting the tag housing to an object. The electronics assembly is adapted to mount into a plurality of differently styled tag housings wherein the tag housings have different configurations of mounting points for mounting the tag housings to objects having different shapes.

In a further embodiment the tag housing mounting points include holes for receiving threaded fasteners. In a further embodiment, the tag housing mounting points include protruding members adapted to fit into mating sockets or holes. In a further embodiment, the electronics assembly includes a printed circuit board, an antenna and an application specific integrated circuit for receiving and transmitting RF signals, and the antenna is formed on the printed circuit board. In a further embodiment, the tag housing comprises an antenna reflector. In a further embodiment the said tag housing is configured to place said electronics assembly a predetermined distance from a metallic mounting surface such that said metallic mounting surface acts as an antenna reflector. In a further embodiment the electronics assembly is incorporated into the tag housing by mechanical interlocking (i.e. snap-in). In a further embodiment, the electronics assembly is attached to the tag housing with a potting material that acts as a dielectric. In a further embodiment, the electronics assembly includes an antenna designed to be compatible with a predetermined housing and object to which the housing is attached. In another embodiment, the tag is adapted for use on a vehicle windshield having a metal film laminate and the metal film laminate acts as an antenna reflector for the tag.

In another embodiment, there is disclose a method of manufacturing an RFID tag including the steps of assembling an electronics assembly having predetermined dimensions; and placing the electronics assembly in a tag housing, wherein the tag housing is one of a plurality of tag housings compatible with the electronics assembly dimensions, the plurality of tag housings have different external dimensions and mounting points for mounting the tag housings and electronics assemblies to objects having different shapes.

In another embodiment, there is disclosed a method of applying an RFID tag to a plurality of objects having different shapes and electrical characteristics. The method includes the steps of manufacturing a plurality of types of RFID tag electronics modules, wherein each type has the same outer dimensions as the other types but different electrical characteristics; manufacturing a plurality of types of tag housings wherein each type is adapted for accepting any of the RFID tag electronic module types, and wherein particular housing types are compatible with the shape and electrical characteristics of a particular one of the plurality of objects; and selecting one of the electronics modules and one of the tag housings that are physically and electrically compatible with a particular one of the objects.

### DESCRIPTION OF THE DRAWINGS

FIG. 1 is a drawing of the copper foil pattern on an exemplary interchangeable RFID tag printed circuit board having a dipole antenna;

FIG. 2 is a drawing of the copper foil pattern on an exemplary interchangeable RFID tag printed circuit board having an aperture antenna;

FIG. 3 is an exploded view isometric drawing showing an exemplary externally-mountable RFID tag insert;

FIG. 4 is an isometric drawing showing an exemplary interchangeable externally mountable RFID tag insert;

FIG. 5 is an exploded view isometric drawing showing an exemplary RFID tag consisted of the RFID tag insert and the mounting bracket for an interchangeable externally mountable RFID tag insert;

FIG. 6 shows an exemplary RFID tag mounted to a license plate;

FIG. 7 is a sensitivity plot for an exemplary externally-mountable RFID tag as shown by FIG. 6; and

FIG. 8 shows sensitivity plots for an exemplary externally-mountable RFID tag on a large metal mounting surface; a RFID tag with a one-inch-wide copper antenna reflector on the back of the bracket, and a RFID tag without a metal reflector mounted on a metalized windshield.

### DETAILED DESCRIPTION

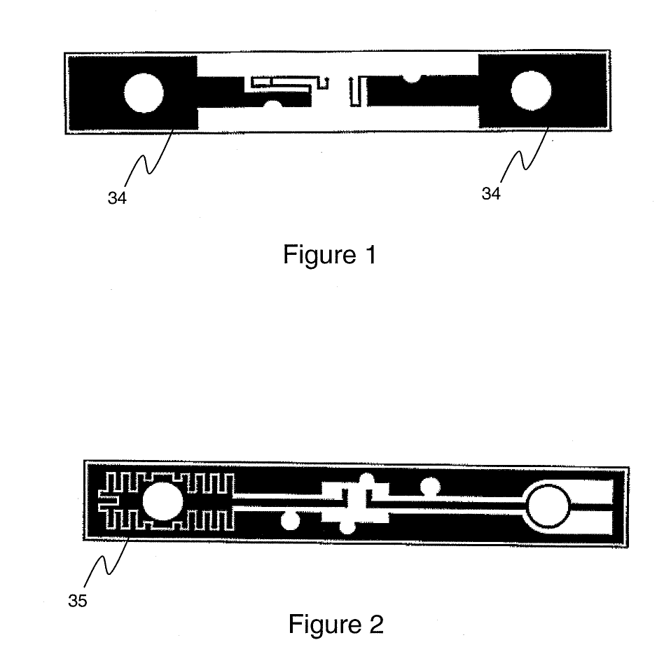

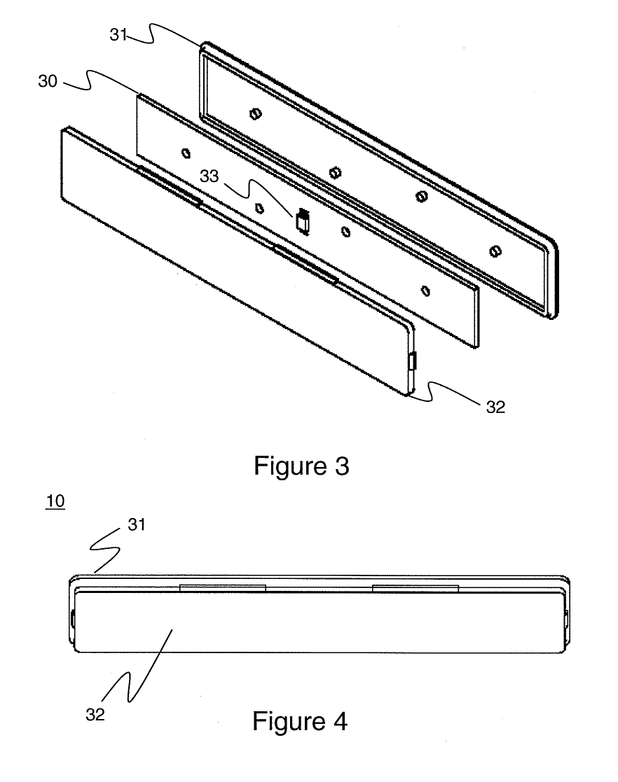

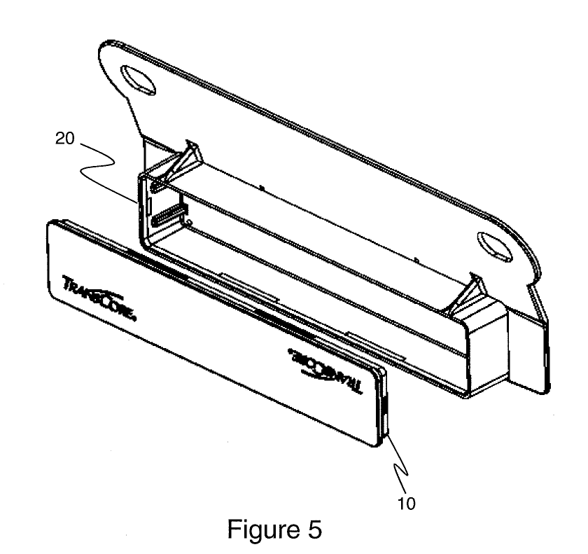

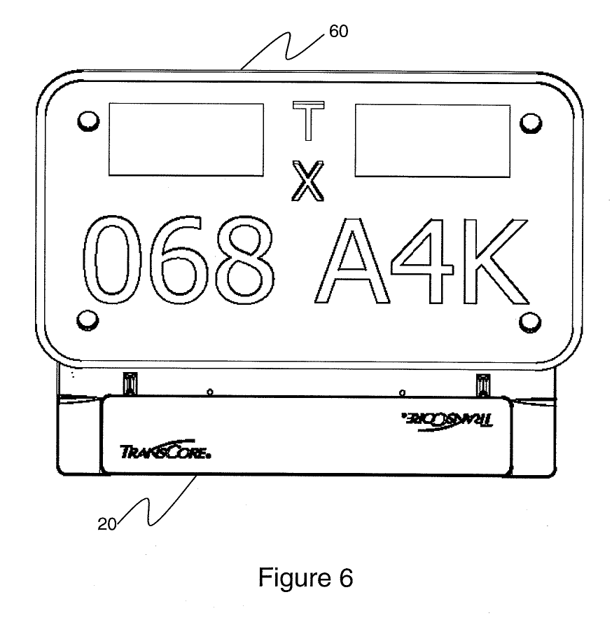

With reference to FIGS. 3 and 5, an exemplary externally-mountable RFID tag consists of an RFID electronics assembly insert 10 and a tag housing (bracket) 20. The RFID electronics assembly insert includes a printed circuit board 30 which includes an ASIC 33, antenna and matching circuit (not shown in FIG. 3). Exemplary antennas 34 and 35 are shown in FIGS. 1 and 2. The RFID electronics assembly insert further comprises front 32 and back 31 housings. FIG. 4 shows the complete RFID electronics assembly insert. The RFID electronics assembly insert is hermetically sealed by over-molding the printed circuit board 30 assembly between the front 32 and back 31 plastic parts. The over-molding process consists of a two stage process. The first process is to inject liquid plastic into the front mold to form the front 32 plastic part with the printed circuit board including ASIC 33 followed by the second process to inject the liquid plastic into the back mold to form the back 31 plastic part to complete the entire molding with the output of the first process, while the plastic is still hot enough to form the final RFID tag 10.

FIG. 5 shows the RFID electronics assembly insert 10 as it mounts into an exemplary bracket 20. In this example, the bracket is to mount the RFID tag to a license plate 60, as shown in FIG. 6.

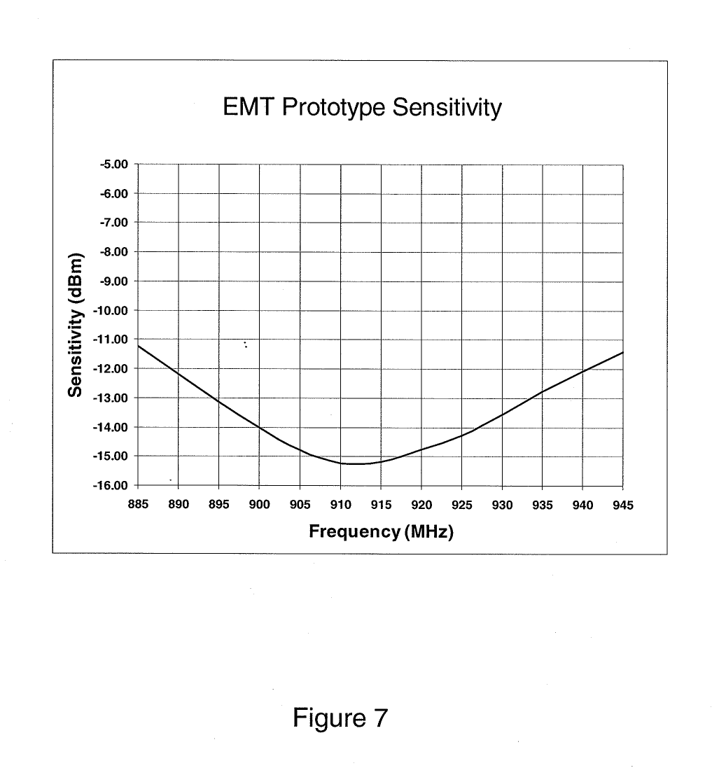

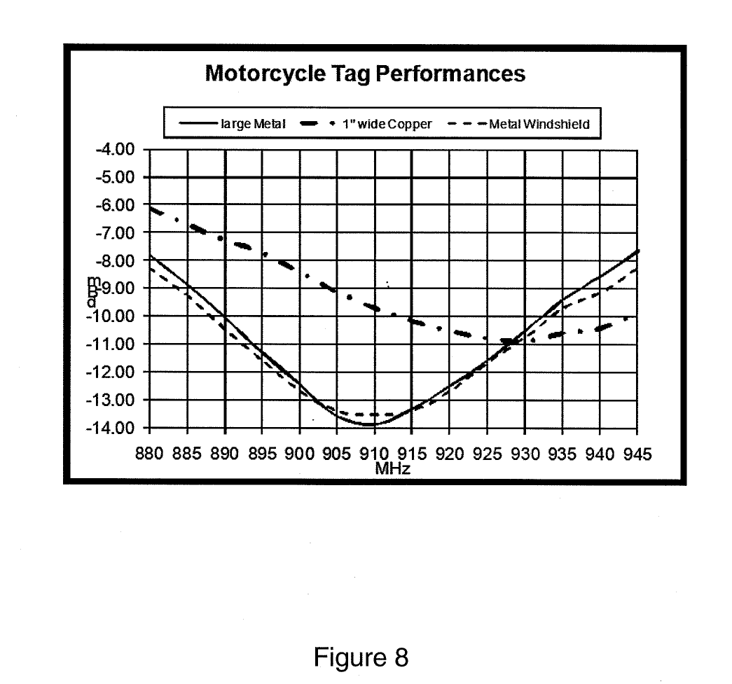

FIG. 7 shows an exemplary sensitivity graph for the RFID tag as shown in FIG. 5, with the bracket being mounted to a motorcycle license plate 60 as shown in FIG. 6. FIG. 8 shows exemplary sensitivity graphs for the same RFID tag mounted in three different configurations. In one configuration, the RFID tag was mounted on a large metal sheet. In that configuration (labeled “large metal”), the mounting bracket incorporates a 1″ wide copper antenna reflector on the back of the bracket. In a second configuration (labeled 1″ wide copper) the mounting bracket incorporates a copper foil antenna reflector on the back of the mounting bracket without the additional metal sheet, In a third configuration (labeled “metal windshield”) the mounting bracket utilizes the built-in laminated metal film within the windshield for the antenna reflector.

I claim:

1. An RFID tag comprising:
an electronics assembly insert and
a tag housing bracket having mounting points for mounting said tag housing bracket to an object wherein said electronics assembly insert is adapted to mount into a plurality of said tag housing brackets wherein said tag housing brackets have different configurations of said mounting points for mounting said tag housing brackets to objects having different shapes.

2. The RFID tag of claim 1, wherein said mounting points include holes for receiving threaded fasteners.

3. The RFID tag of claim 1, wherein said mounting points include protruding members adapted to fit into mating sockets or holes.

4. The RFID tag of claim 1, wherein said electronics assembly insert comprising a printed circuit board, an antenna and an application specific integrated circuit for receiving and transmitting RF signals, wherein said antenna is formed on said printed circuit board.

5. The RFID tag of claim 1, wherein said tag housing bracket comprises an antenna reflector.

6. The RFID tag of claim 4, wherein said tag housing bracket is configured to place said electronics assembly insert predetermined distance from a metallic mounting surface such that said metallic mounting surface acts as an antenna reflector.

7. The RFID tag of claim 1, wherein said electronics assembly is incorporated into said tag housing bracket by mechanical interlocking.

8. The RFID tag of claim 1, wherein said electronics assembly insert is attached to said tag housing with a potting material that acts as a dielectric.

9. The RFID tag of claim 1, wherein said electronics assembly insert comprises an antenna designed to be compatible with a predetermined housing and object to which said housing is attached.

10. The RFID tag of claim 1, wherein said tag is adapted for use on a vehicle windshield comprising a laminated metal film and wherein said laminated metal film acts as a reflector for the tag.

11. A method of manufacturing an RFID tag comprising:
assembling an electronics assembly insert having predetermined dimensions;
placing said electronics assembly insert in a tag housing bracket, wherein said tag housing bracket is one of a plurality of tag housing brackets compatible with said electronics assembly dimensions, said plurality of tag housing brackets having different external dimensions and mounting points for mounting said tag housing brackets and electronics assembly inserts to objects having different shapes.

12. A method of applying an RFID tag to a plurality of objects having different shapes and electrical characteristics, said method comprising:
manufacturing a plurality of types of RFID tag electronics modules, wherein each type has the same outer dimensions as the other types but different electrical characteristics;
manufacturing a plurality of types of tag housings wherein each type is adapted for accepting any of said RFID tag electronic module types, and wherein particular said housing types are compatible with the shape and electrical characteristics of a particular one of said plurality of objects; and
selecting one of said electronics modules and one of said tag housings that are physically and electrically compatible with a particular one of the objects.
